(19) United States
(12) Patent Application Publication
(10) Pub. No.: US 2008/0112135 A1
(43) Pub. Date: May 15, 2008

(54) Outdoor Medium Voltage Drive

(75) Inventors: John D. Kleinecke, Houston, TX (US); Mike C. Daskalos, Magnolia, TX (US); Osamu Tanaka, Tokyo (JP)

Correspondence Address: BANNER & WITCOFF, LTD., 1100 13th STREET, N.W., SUITE 1200, WASHINGTON, DC, 20005-4051, US

(73) Assignee: Toshiba International Corporation, Houston, TX (US)

(21) Appl. No.: 11/558,560

(22) Filed: Nov. 10, 2006

(51) Int. Cl. H05K 7/20; F28F 1/10; F28D 15/00; F28F 1/00

(52) U.S. Cl. 361/696; 165/185; 165/104.33; 165/177; 361/701

(57) ABSTRACT

A heat-dissipating cabinet structure may use a heat exchanger mounted at a boundary between an interior cabinet portion and an exterior portion, and heat-generating devices medium-voltage devices (such as high isolation IGBT or diode devices) may be mounted on the interior portion of the heat exchanger. The IGBT or diode devices may be electrically grounded within the cabinet such that contact with the external portion of the heat exchanger does not compromise the required clearance and creepage distances between the device's terminals and its base. Heat dissipating elements (e.g., fins, coils, etc.) may be formed at the outside portion of the heat exchanger to facilitate dissipation. A fan may be used to drive airflow over the exterior portion of the heat exchanger (and its dissipation elements), and the airflow may be directed by an airflow housing.

### BACKGROUND

High- and medium-voltage (e.g., greater than 2000 volts) power electronics assemblies, such as adjustable speed drives, often use groups of power transistors and diodes switched on and off in a predetermined timing sequence to supply the level and frequency of power desired. Because of the high voltage levels in which they operate (e.g., 3300 volts, 4500 volts, 6500 volts, etc.), and the associated levels of current, these devices tend to generate significant amounts of excess heat.

FIG. 1 illustrates a known approach to dissipating this heat. As shown, a cabinet 100 may house a group of power devices 101. The devices 101 may be attached to a heat exchanger 102, and a fan assembly 103 may be used to draw air through the cabinet 100 to dissipate the excess heat generated by the devices 101. Doing so, however, results in airborne contaminants being deposited on the devices 101 such that, over time, the devices 101 will require maintenance and/or cleaning. The contaminants may also interfere with the operation of the devices 101, or may cause even more heat to build up (e.g., as the contaminants may tend to trap heat) and reduce the lifespan of the devices 101.

The devices 101 used in medium-voltage drive assemblies today do not have adequate voltage isolation between their terminals and their base to support the potential developed between their terminals and ground when the base is grounded. Accordingly, as shown in FIG. 1, the heat exchanger 102 may be at the same potential as the base of the devices 101, and may have a 2400 volt (or more) potential difference with respect to ground, so the heat exchanger 102 must be maintained insulated from the grounded chassis of the cabinet 100.

### SUMMARY

This Summary is provided to introduce a selection of concepts in a simplified form that are further described below in the Detailed Description. This Summary is not intended to identify key features, essential features, or required advantages of the claimed subject matter, or in limiting the scope of the appended claims.

### BRIEF DESCRIPTION OF THE DRAWINGS

FIG. 1 illustrates an example of a prior art configuration for dissipating heat.

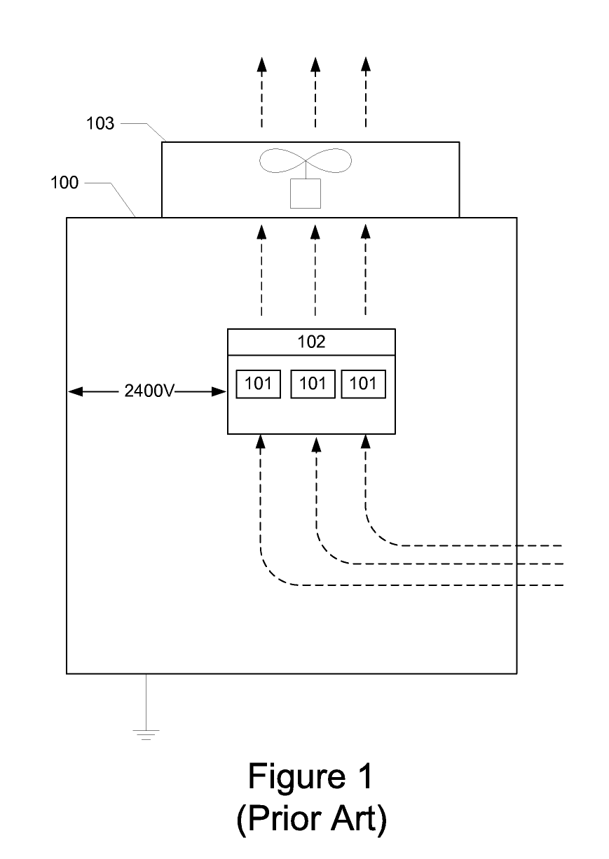

FIG. 2 illustrates an example of an improved configuration for dissipating heat.

### DETAILED DESCRIPTION

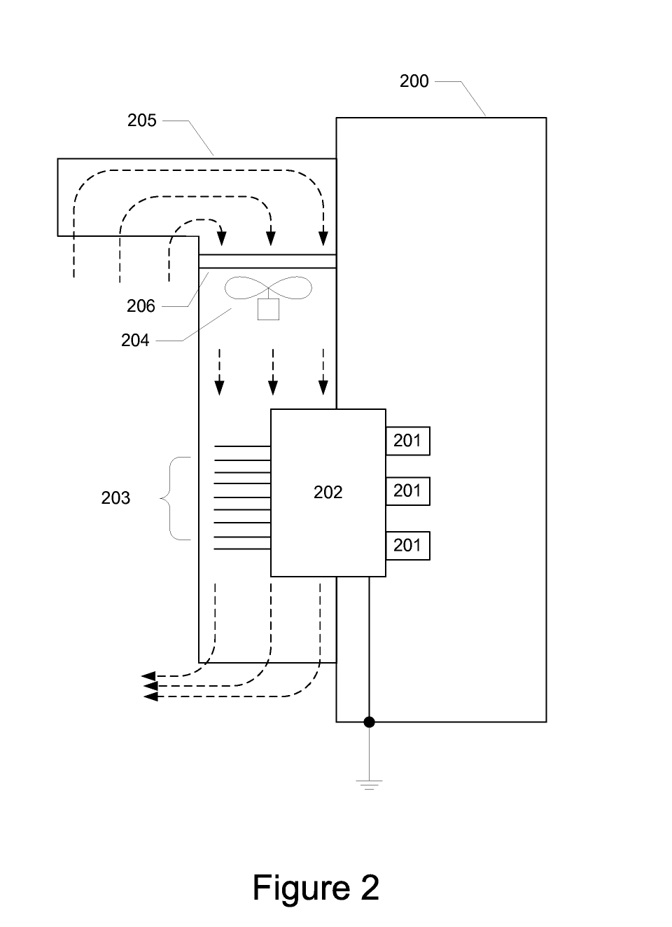

FIG. 2 illustrates an example of an improved configuration for dissipating heat in a medium-voltage (or higher) power drive. As shown, a cabinet 200 may have its chassis, or other surface, connected to a ground potential. The cabinet 200 may be weather resistant. For example, the external surface of the cabinet 200 may be coated with waterproof and corrosion-resistant materials to allow the cabinet 200 to be placed in an outside environment (e.g., exposed to the elements such as unfiltered air, precipitation, etc.). The cabinet 200 may also be sealed to prevent moisture and other contaminants from entering its interior. If desired, additional climate control devices (e.g., air conditioning, dehumidifiers, heating, etc.) may be used in the internal portion of the cabinet 200 to further help heat dissipation and maintain device 201 operation.

Within the cabinet 200 may be one or more power devices 201. These power devices have a high isolation capability from their terminals to their base. An example of such a device is the Mitsubishi Type CM400HG-66H IGBT, another power transistor or diode device in the medium-voltage range with high isolation (e.g., isolation voltage levels of 10.2 kv or more), or any other such high isolation power transistor or diode device. The devices 201 may be mounted on a grounded heat exchanger 202. Heat exchanger 202 may have a body made of any type of heat absorbing material, such as aluminum or other metal, and may be coupled to the devices 201 using heat transfer mounting materials, such as thermally conductive fasteners (e.g., metallic bolts, screws, etc.), adhesives and/or pastes. As the heat exchanger 202 can be grounded, it may be installed with one portion on the interior of the cabinet 200, and another portion external to the cabinet 200, such that the exchanger 202 forms part of a barrier between the cabinet 200 interior and external elements without the risk of electrical breakdown or shock due to inadvertent contact with personnel. To preserve this barrier, an moisture/contaminant seal may be placed at the junction between the exchanger 202 and the cabinet 200 wall, to prevent moisture and other contaminants from entering the cabinet 200 interior.

The exchanger 202 may have a plurality of heat dissipating, or radiating, elements 203 to help transfer heat from the exchanger 202 body to the air surrounding the exterior of the cabinet 200. The elements 203 may be, for example, heat-dissipating metallic fins (e.g., aluminum or other metal or metal alloy), radiator coils, or any other desired dissipating or radiating configuration that absorbs and transfers heat away from the devices 201 and to the air surrounding the eternal portion of the exchanger 202. The elements 203, and the exchanger 202 body, may be made of a heat-conducting material, such as aluminum, metal or metal alloy, and may also be corrosion resistant (e.g., stainless steel or other resistant material). One or more fans 204 may also be used to generate air flow around the exterior portion of the exchanger, and this air flow may serve to draw heat away from the devices 201 and into the exterior air.

The cabinet 200 may be coupled to an airflow housing 205 to guide the airflow through the heat dissipation elements 203 and to protect against certain outdoor elements (e.g., prevent precipitation from entering the airflow). Airflow housing 205 may be, for example, an air duct. The air flowing through dissipation elements 203 may be unfiltered air obtained directly from the outside environment, or it may pass through one or more filters 206 before reaching the elements 203 to remove external contaminants and to reduce the risk of animals/birds/insects interfering with the operation of the exchanger 202.

The airflow housing 205 and fan 204 are optional, however, and may be omitted if desired. For example, the heat exchanger 202 may simply have its external portion directly exposed to the outdoor elements. This may be advantageous, for example, in locations where the outdoor climate is cool enough such that additional cooling through forced air is unnecessary. In such a configuration, the exchanger 202 body and dissipation elements 203 may be made of corrosion-resistant metals and/or coated with corrosion- and contaminant-resistant material, to help prolong life.

Using one or more of the features and approaches described above, heat management in power devices may be effectively achieved. Although the description above provides illustrative examples and sequences of actions, it should be understood that the various examples and sequences may be rearranged, divided, combined and subcombined as desired. For example, steps and features described may be omitted, or additional steps and features may be added. Accordingly, although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

We claim the following:

1. A medium voltage power drive system, comprising:
a cabinet having an interior;
an electrically grounded heat exchanger mounted on a wall of said cabinet, wherein a portion of said exchanger lies on an inside portion of said cabinet, and a portion of said exchanger lies outside of said cabinet; and
a plurality of high isolation power transistor and diode devices thermally coupled to an interior side of said heat exchanger, wherein said power transistor and diode devices are also electrically grounded.

2. The system of claim 1, wherein said heat exchanger comprises a plurality of fins on said portion lying outside said cabinet.

3. The system of claim 2, further comprising a fan positioned to draw air over said fins.

4. The system of claim 3, further comprising an airflow housing around said fan and fins.

5. The system of claim 1, wherein said inside portion of said cabinet is sealed within said cabinet, and wherein said portion of said exchanger lying outside said cabinet is exposed to outdoor elements.

6. The system of claim 1, wherein said high isolation transistor and diode devices include an isolation voltage of 10.2 kV or greater.

7. A medium voltage power drive system, comprising:
an electrically-grounded cabinet having an interior protected from outdoor elements;
an electrically grounded heat exchanger mounted on a wall of said cabinet, wherein an interior portion of said exchanger lies in said interior portion of said cabinet, and an exterior portion of said exchanger lies external to said cabinet and is exposed to outdoor elements, said exterior portion of said exchanger including a plurality of heat dissipating elements;
a plurality of high isolation power transistor and diode devices thermally coupled to an interior side of said heat exchanger, said power transistor and diode devices being electrically grounded;
an airflow housing coupled to an exterior of said cabinet; and
a fan positioned to draw air through said airflow housing and across said heat dissipating elements.

8. The system of claim 7, wherein said power transistor and diode devices are high isolation medium voltage IGBT devices.

9. The system of claim 8, wherein said high isolation medium voltage IGBT devices support an isolation voltage of 10.2 kV or greater.

10. The system of claim 7, wherein said heat exchanger includes a body made of aluminum.

11. The system of claim 7, wherein said heat dissipating elements are made of a corrosion resistant, heat-conducting material.
